(19) United States
(12) Patent Application Publication
(10) Pub. No.: US 2011/0108416 A1
(43) Pub. Date: May 12, 2011

(54) MAGNETRON SPUTTER

(76) Inventors: Cheng-Tsung LIU, Kaohsiung City (TW); Ming-Chih Lai, Kaohsiung City (TW)

(21) Appl. No.: 12/615,913

(22) Filed: Nov. 10, 2009

(51) Int. Cl. C23C 14/35

(52) U.S. Cl. 204/298.21

(57) ABSTRACT

A magnetron sputter comprises a carrier, a magnet assembly, at least a middle magnetic ring, a target and at least a conducting magnetic ring. The magnet assembly is disposed on a carrying surface of the carrier comprising a permanent magnet and an external magnetic ring. The middle magnetic ring is disposed between the permanent magnet and the external magnetic ring of the magnet assembly. The target is disposed above the magnet assembly having a first surface which faces the carrying surface. The conducting magnetic ring is disposed on the first surface.

### FIELD OF THE INVENTION

The present invention is generally relating to a magnetron sputter, more particularly to a magnetron sputter which can enhance sputtering efficiency and improve use lifetime of target.

### BACKGROUND OF THE INVENTION

Semiconductor industry is generally employed in various fields, such as information, communication, consumer electronics, industrial instruments and transportation. For example, ultra purity aluminum-titanium sputtering used in semiconductor fabricating industry, silver-aluminum alloy and complex alloy phase change sputtering used in compact disk fabricating industry, indium tin oxide (ITO) among transparent conductive oxide (TCO) film and aluminum alloy circuit layer sputtering used in TFT-LCD fabricating process, etc. The magnetron sputtering method mentioned within the foregoing fabricating processes is employed for coating which is to form a thin film on substrates to allow the substrate surface having characters of good-looking, anti-friction, heat resistance, corrosion resistance, etc, in which the thin film may be made of same or different material to encapsulate substrates.

Sputter basically employs ion sputtering theory, in which sputtering phenomenon occurs when particles with high energy (normally positive ions accelerated by electric field) impact solid surface, atoms and molecules located on the solid surface physically project after energy-exchanging with the particles. Sputtering environment is established by that the accelerated electrons generated between two poles of electric field impact pre-filled inert gas (normally argon gas) within coating chamber to form positively charged gas ions. The positive ions are attracted by the cathode which serves as a sputter target to impact the cathode surface and energy-exchange with the target surface atoms, and then the target surface atoms with energy will squash the atoms under the target surface to make them shift and generate active force. As a result, the target surface atoms are impacted by the active force to physically project and finally deposit on substrates (normally anode) to form a thin film.

In general, so called dc sputtering is that a direct voltage is provided between two poles of sputter, which employs gas glow discharge to generate positive ions for impacting the target surface atoms. In most dc sputtering application, the positively charged particles are in rectilinear motion along electric field direction so gas ionization rate is low, because most the gas atoms are uncharged unable to be accelerated for sputtering resulting in low sputtering efficiency. Therefore, a magnetic field is added under the target so as to improve ionization rate and sputtering efficiency of gas. Magnetron sputtering is to mount an annular magnet target onto the target surface to control electrons motion. The additional magnetic field of any sputtering apparatus serves for extending moving trail of electrons, which mainly allows electrons impact taking place as many times as possible to increase plasma density, thereby enhancing sputtering efficiency.

The known magnetron sputter structure could cause problems on the target surface, such as non-uniform ion distribution and annular etching shape, and if the etching area is too big, the target cannot be used any more.

As shown in FIG. 1, the known magnetron sputter 100 typically comprises an iron plate 110, a permanent magnet 120, an external magnetic ring 130 disposed around the permanent magnet 120 and a target 140. The permanent magnet 120 and the external magnetic ring 130 are disposed on the iron plate 110, and the target 140 is disposed above the permanent magnet 120 and the external magnetic ring 130. The permanent magnet 120 has a first magnet N pole and a first magnet S pole, and the external magnetic ring 130 has a second magnet N pole and a second magnet S pole. The first magnet N pole of the permanent magnet 120 and the second magnet S pole of the external magnetic ring 130 face the target 140. The first magnet S pole of the permanent magnet 120 and the second magnet N pole of the external magnetic ring 130 face one surface 111 of the iron plate 110. When the magnetron sputter 100 is activated, since magnetic line of force within magnetic field travels along fixed direction, partially special area of the target 140 could be overused, etched and even penetrated, which results in lowering usage rate of the target 140 as well as electrons and ions within the magnetron sputter 100 are affected by electromagnetic field so coating efficiency and uniformity of substrate will become worse as to cause problem of low sputtering efficiency.

### SUMMARY

A primary object of the present invention is to provide a magnetron sputter which comprises a carrier, a magnet assembly, at least a middle magnetic ring, a target and at least a conducting magnetic ring. The carrier has a carrying surface, and the magnet assembly is disposed on the carrying surface of the carrier having a permanent magnet and an external magnetic ring disposed around the permanent magnet. The middle magnetic ring is disposed between the permanent magnet and the external magnetic ring. The target is disposed above the magnet assembly having a first surface facing the carrying surface and a second surface opposite to the first surface. The conducting magnetic ring is disposed on the first surface of the target. Extra elements such as the middle magnetic ring, the conducting magnetic ring and the external coil are added to the magnetron sputter without changing original structure for adjusting intensity and direction of magnetic field so as to improve sputtering efficiency and use lifetime of the target, thereby lowering cost and increasing economic efficiency.

A secondary object of the present invention is to provide a magnetron sputter which further comprises an external coil. The external coil is disposed on the carrying surface of the carrier and positioned outside the magnet assembly to change use scope of the target capable of preventing the target from being etched and penetrated and increasing use lifetime of the target.

### DESCRIPTION OF THE DRAWINGS

FIG. 1 is a cross-sectional view illustrating a known magnetron sputter

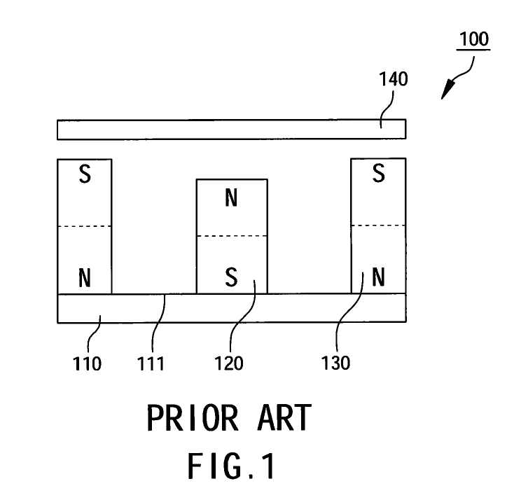

FIG. 2 is a perspective exploded view illustrating a magnetron sputter in accordance with a preferred embodiment of the present invention.

FIG. 3 is a cross-sectional view illustrating the magnetron sputter in accordance with a preferred embodiment of the present invention.

### DETAILED DESCRIPTION OF THE INVENTION

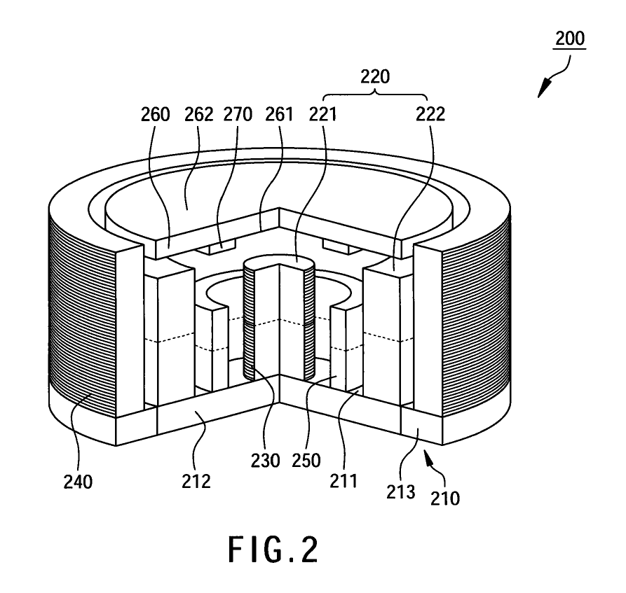

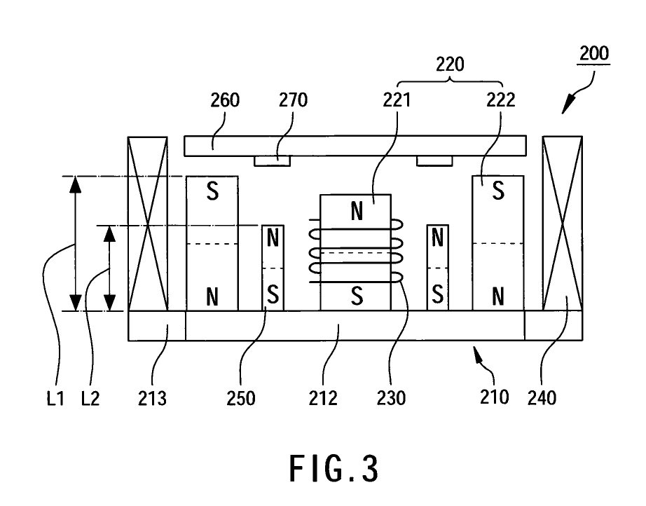

With reference to FIGS. 2 and 3, a magnetron sputter 200 in accordance with a preferred embodiment of the present invention comprises a carrier 210, a magnet assembly 220, an internal coil 230, an external coil 240, at least a middle magnetic ring 250, a target 260 and at least a conducting magnetic ring 270. The carrier 210 has a carrying surface 211, the magnet assembly 220 is disposed on the carrying surface 211 of the carrier 210 comprising a permanent magnet 221 and an external magnetic ring 222 disposed around the permanent magnet 221. Within this embodiment, the permanent magnet 221 has a shape of pillar, a preferred diameter about 12 mm and a preferred radial thickness about 20 mm. The external magnetic ring 222 also has a preferred internal diameter about 38 mm, a preferred external diameter about 50 mm and a preferred radial thickness about 22 mm. The permanent magnet 221 has a first magnet N pole and a first magnet S pole, and the external magnetic ring 222 has a second magnet N pole and a second magnet S pole. The first magnet N pole of the permanent magnet 221 and the second magnet S pole of the external magnetic ring 222 face the target 260. The first magnet S pole of the permanent magnet 221 and the second magnet N pole of the external magnetic ring 222 face the carrying surface 211 of the carrier 210. The internal coil 230 winds the permanent magnet 221 to strengthen source of magnetic field and the preferred winding turn number is about 40 turns. The external coil 240 is disposed on the carrying surface 211 of the carrier 210 and positioned outside the magnet assembly 220 to change lowermost location of axially magnetic field, and whose preferred turn number is about 900 turns. The middle magnetic ring 250 is disposed within a gap between the permanent magnet 221 and the external magnetic ring 222 of the magnet assembly 220 to strengthen magnetic field intensity of the gap and change magnetic field intensity within the magnetron sputter 200. The middle magnetic ring 250 has an N pole facing the target 260 and an S pole facing the carrying surface 211 of the carrier 210, and whose preferred internal diameter, external diameter and radial thickness are about 15 mm, 21 mm, 15 mm respectively. The target 260 is disposed above the magnet assembly 220 having a first surface 261 facing the carrying surface 211 and a second surface 262 opposite to the first surface 261. The conducting magnetic ring 270 is disposed on the first surface 261 of the target 260 to radially direct magnetic line of force-direction of magnetic field allowing magnetic field-direction to parallel the target 260. The preferred internal diameter, external diameter and radial thickness of the conducting magnetic ring 270 are about 20 mm, 28 mm, 1 mm respectively. Within this embodiment, the conducting magnetic ring 270 corresponds to the middle magnetic ring 250.

Besides, as shown in FIGS. 2 and 3, the carrier 210 within this embodiment has a middle conducting magnetic portion 212 and an external aluminum-ring portion 213. The middle conducting magnetic portion 212 is an iron plate employed for directing magnetic line of force-direction of magnetic field to produce a closing magnetic field path. The preferred diameter and radial thickness of the middle conducting magnetic portion 212 are about 50 mm, 10 mm respectively. The magnet assembly 220 and the middle magnetic ring 250 are disposed on the middle conducting magnetic portion 212, and the external coil 240 is disposed on the external aluminum-ring portion 213. As shown in FIG. 3, the external magnetic ring 222 has a first height L1 and the middle magnetic ring 250 has a second height L2, in which the second height L2 is less than or equal to the first height L1. The present invention without changing original structure of the magnetron sputter 200 adds some elements such as the middle magnetic ring 250, the conducting magnetic ring 270 and the external coil 240 to adjust intensity and direction of magnetic field within the magnetron sputter 200, which allows traveling direction of magnetic line of force not to excessively concentrate on specific area of the target 260 so as to prevent the target 260 from being etched and penetrated and increase use lifetime of the target 260, thereby lowering cost and increase sputtering efficiency up to 40%. Moreover, quality of that the magnetron sputter 200 gives sputter on substrate could be affected by disposing position and size of the conducting magnetic ring 270 and the middle magnetic ring 250.

When this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A magnetron sputter at least comprising:
a carrier having a carrying surface;
a magnet assembly disposed on the carrying surface of the carrier having
a permanent magnet and an external magnetic ring disposed around the permanent magnet;
at least a middle magnetic ring disposed between the permanent magnet and the external magnetic ring of the magnet assembly;
a target disposed above the magnet assembly having a first surface facing the carrying surface and a second surface opposite to the first surface; and
at least a conducting magnetic ring disposed on the first surface of the target.

2. The magnetron sputter in accordance with claim 1, further comprising an internal coil winding the permanent magnet.

3. The magnetron sputter in accordance with claim 1, further comprising an external coil disposed on the carrying surface of the carrier and positioned outside the magnet assembly.

4. The magnetron sputter in accordance with claim 1, wherein the conducting magnetic ring corresponds to the middle magnetic ring.

5. The magnetron sputter in accordance with claim 1, wherein the carrier has a middle conducting magnetic portion and an external aluminum-ring portion, the magnet assembly and the middle magnetic ring are disposed on the middle conducting magnetic portion.

6. The magnetron sputter in accordance with claim 3, wherein the carrier has a middle conducting magnetic portion and an external aluminum-ring portion, the external coil is disposed on the external aluminum-ring portion.

7. The magnetron sputter in accordance with claim 1, wherein the middle magnetic ring has an N pole facing the target and an S pole.

8. The magnetron sputter in accordance with claim 7, wherein the S pole of the middle magnetic ring faces the carrying surface of the carrier.

9. The magnetron sputter in accordance with claim 1, wherein the external magnetic ring has a first height, the middle magnetic ring has a second height, the second height is less than or equal to the first height.

10. The magnetron sputter in accordance with claim 5, wherein the middle conducting magnetic portion is an iron plate.
